(19) United States
(12) Patent Application Publication
(10) Pub. No.: US 2010/0230771 A1
(43) Pub. Date: Sep. 16, 2010

(54) METHODS AND ARRANGEMENT FOR DIFFUSING DOPANTS INTO SILICON

(75) Inventors: David K. Fork, Los Altos, CA (US); Kenta Nakayashiki, Sandvika (NO)

Correspondence Address: FAY SHARPE LLP / XEROX - PARC, 1228 EUCLID AVENUE, 5TH FLOOR, THE HALLE BUILDING, CLEVELAND, OH, 44115, US

(73) Assignee: PALO ALTO RESEARCH CENTER INCORPORATED, Palo Alto, CA (US)

(21) Appl. No.: 12/403,757

(22) Filed: Mar. 13, 2009

(51) Int. Cl. H01L 31/04; H01L 21/38

(52) U.S. Cl. 257/431; 438/542; 438/558; 257/E21.466

(57) ABSTRACT

A method for diffusing two dissimilar dopant materials onto a semiconductor cell wafer in a single thermal processing step. The method includes placing a first dopant source on a semiconductor cell wafer, placing said cell wafer into a thermal processing chamber comprising one or more cell wafer slots, subjecting said cell wafer to a thermal profile; and annealing said cell wafer in the presence of a second dopant source.

### BACKGROUND

The present disclosure relates generally to bi-facial solar cells and more particularly to providing a method and arrangement for diffusing dopants into silicon with a reduced number of high temperature steps.

A solar cell, or photovoltaic cell, is a device that converts solar energy into electricity by the photovoltaic effect. The photovoltaic effect is the basic physical process through which photons of different energy are either reflected or absorbed by a solar cell. Those photons that are absorbed generate energy. Solar cells are commonly formed as a large-area, single layer p-n (positive-negative) junction cells. These cells are typically made using silicon wafers that are doped to include one or more p-type doped regions and one or more n-type doped regions. Typically, phosphorous is used to dope silicon to create an n-type layer, and boron is used to dope silicon to form a p-type layer. When p-type silicon is placed in immediate contact with a piece of n-type silicon, a diffusion of electrons occurs from the region of high electron concentration (the n-type side of the junction) into the region of low electron concentration (p-type side of the junction). When electrons diffuse across the p-n junction, they recombine with holes on the p-type side. As electrons flow through the material, they produce electricity. When a p-n junction covers only one side of a wafer, a cell is mono-facial and only photo-active with respect to light contacting the front side of the cell. By additionally providing a thin junction layer on the opposite side of the cell, the cell can become bi-facial and photoactive on each side of the cell.

Fabrication of a bi-facial solar cell generally requires two separate high-temperature diffusion steps in order to form an emitter and a back surface field. This results in either an n+-p-p+or p+-n-n+ structure. First, silicon wafers are processed in a wet bench for surface cleaning and/or surface texturing. The cell wafers are then set in a BBr₃ furnace to form a p+ region. After a first diffusion process, a diffusion barrier, generally comprising SiNₓ, is deposited on a single side of the wafer. A surface etching process is performed to remove the diffused region on the other side of the wafer. A second diffusion process is then implemented using a POCl₃ furnace to produce an n+ region. This process is followed by a wet chemical process to remove the surface residue, phosphosilicate glass and/or borosilicate glass. The final n⁺-p-p⁺/^{p+}-n-n⁺structure is completed by edge isolation.

Japanese Patent Number 2001077386 describes fabrication of p n⁺-p-p⁺/p⁺-n-n⁺ structure in a conventional tube furnace. First, silicon wafers are processed in a wet bench for surface cleaning and/or surface texturing. The wafers are then set in a BBr₃ furnace to form p⁺ region with a front-to-front/back-to-back configuration. After the first diffusion process, the wafers are re-arranged to back-to-back/front-to-front configuration to avoid cross diffusion. A second diffusion process is commenced to form the n⁺ region in a POCl₃ furnace, followed by a wet chemical process to remove the surface residue, phosphosilicate glass and/or borosilicacte glass. The structure is then completed by edge isolation. This method does not require a diffusion barrier; however, it is necessary to perform two diffusion processes in a conventional tube to achieve n⁺-p-p⁺/p⁺-n-n⁺ structure.

U.S. Pat. No. 5,972,784 describes a solar cell fabrication process that does not require two diffusion processes or a diffusion barrier deposition to form n⁺-p-p⁺/p⁺-n-n⁺structure. The solar cell wafers are placed in between phosphorous (P) and boron (B) dopant source wafers for a formation of n+ and p+ regions, respectively. Upon heating, the thermal diffusion takes place whereby the dopant leaves the source wafers and becomes diffused into the cell wafers in order to create an emitter and a back surface field. The n⁺-p-p⁺/p⁺-n-n⁺ structure is formed by a single high temperature process; however, the throughput is generally lower (almost 50%) compared to the conventional processing because P and B source wafers need to be loaded into the diffusion furnace with the cell wafers.

Therefore, there is a continued need to minimize the number of high temperature steps for cost-effective photovoltaic modules by reducing the cell processing time.

### BRIEF DESCRIPTION

The present disclosure is directed to a method for diffusing two dissimilar dopant materials onto a semiconductor cell wafer in a single thermal processing step. The method includes placing a first dopant source on a semiconductor cell wafer, placing said cell wafer into a thermal processing chamber comprising one or more cell wafer slots, subjecting said cell wafer to a thermal profile; and annealing said cell wafer in the presence of a second dopant source.

The invention is further directed to a method for doping a semiconductor substrate. The method includes placing a first dopant source on a first surface of a first cell wafer, placing a second dopant source on a second surface of a second cell wafer, and arranging said first and second cell wafer in a tube furnace such that said first and second surfaces face one another.

Embodiments of the present invention are further directed to a semiconductor arrangement for dopant diffusion into silicon. The semiconductor arrangement includes at least a first and second cell wafer, each having a first and second side, a p-type dopant source deposited on the first side of said first and second cell wafer, and an n-type dopant source deposited on the second side of said first and second cell wafer, wherein said first and second cell wafer are loaded into a furnace with back-to-back/front-to-front configuration.

These and other non-limiting aspects and/or objects of the disclosure are more particularly described below.

### BRIEF DESCRIPTION OF THE DRAWINGS

FIG. 1 illustrates a cross-sectional view of the structure of a bi-facial solar cell;

FIG. 2 illustrates a process sequence for achieving n+-p-p+/p+-n-n+ cell structure;

FIG. 3a illustrates a depiction of a conventional cell loading configuration for diffusion;

FIG. 3b illustrates a loading configuration of cells for diffusion according to the present invention;

FIG. 4 illustrates a side view of conventional wafers with diffusion barrier layer on top of the dopant;

FIG. 5a illustrates a cross sectional view of the deposition of dopant and diffusion barrier on the same side of the silicon substrate to eliminate the edge isolation process;

FIG. 5b illustrates a rear side view of a dopant and diffusion barrier on the same side of the silicon substrate to eliminate the edge isolation process.

FIG. 6a illustrates a cross section view of a dopant and diffusion barrier on the same side of the silicon substrate where the dopant source is covered with the diffusion barrier;

FIG. 6b illustrates a rear side view of a dopant and diffusion barrier on the same side of the silicon substrate where the dopant source is covered with the diffusion barrier;

### DETAILED DESCRIPTION

Aspects of the exemplary embodiment relate to a simplified method and arrangement for dopant diffusion into silicon; however, it is to be appreciated that this exemplary method and arrangement may be used for any known purpose. In particular, the invention will be explained with reference to solar cells, but the invention is not limited thereto but may find application in semiconductor devices generally. In addition, the invention will mainly be described with reference to n⁺-p-p⁺/p⁺-n-n⁺ cell structure. The invention is not limited thereto and may be applied to the formation of various cell structures.

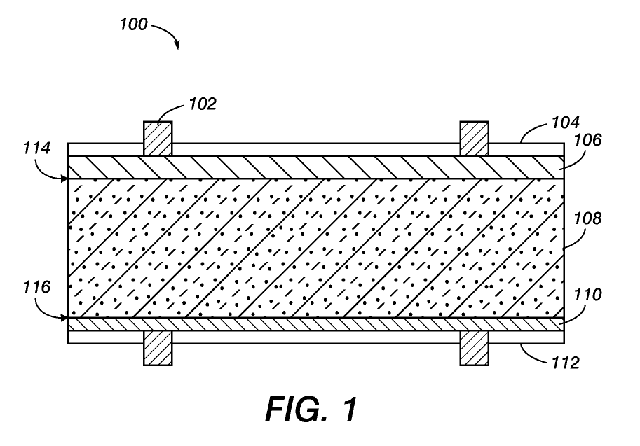

FIG. 1 represents a common configuration of a bi-facial solar cell 100. The solar cell 100 comprises a substrate 108 including a front 114 and rear surface 116 diffused with a dopant. The solar cell 100 of FIG. 1 includes only one substrate 108; however, it is to be appreciated that the solar cell according to the present invention may alternatively include two or more substrates. The front surface 114 comprises an emitter 106 and the back surface 116 comprises a back surface field (BSF) 110. The emitter layer 106 may optionally be covered with an anti-reflection/passivation layer 104. Passivation layers reduce surface recombination, whereby electrons and holes combine with each other. When recombination occurs, charge carriers are eliminated, thereby reducing the efficiency of the cell. The application of an anti-reflection layer, such as silicon nitride (SiN), titanium dioxide (TiO₂), and similar materials, may be used with the passivation layer to reduce the fraction of incident radiation reflected off solar cell. Since SiN can be employed both to reduce surface recombination and as an anti-reflection layer, SiN is widely used for combination anti-reflection/passivation layers. However, it is to be appreciated, that these materials are not intended to be limiting as any material known in the art may alternatively be used. A passivation layer 112 may also be applied over the BSF layer 110 as shown in FIG. 1. The solar cell 100 may further include metal contacts 102 made to both the emitter 106 and back surface field 110 sides of the solar cell 100 that may be connected to an external load (not shown).

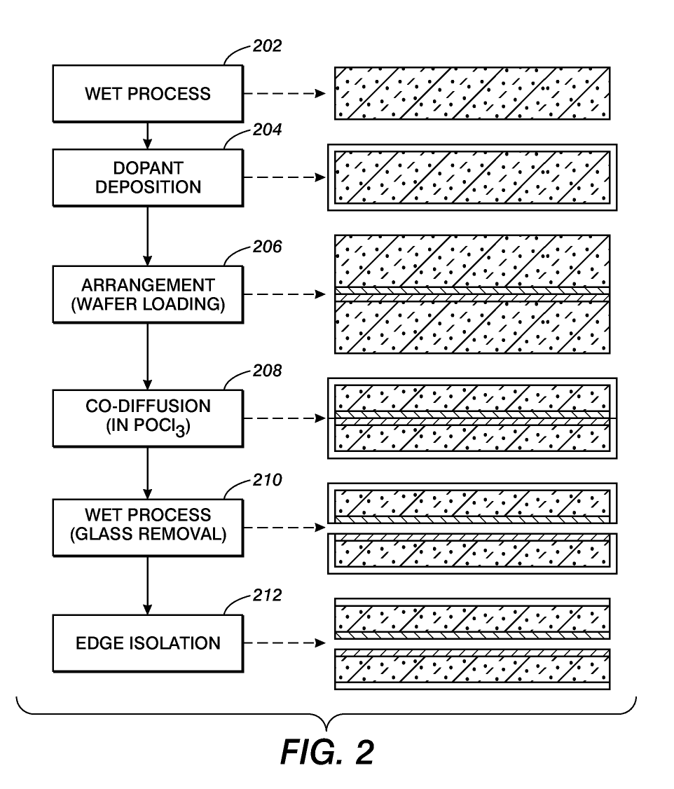

FIG. 2 illustrates an exemplary process sequence for obtaining the n⁺-p-p⁺/p⁺-n-n⁺ cell structure. Silicon cell wafers are first processed in a wet bench designed for wet etching and cleaning/texturing of cell wafers 202. A p-type dopant, typically from the group IIIA of the periodic table such as boron or aluminum, is then deposited on one side of the wafer using any method well know in the art 204. Common deposition methods include screen-printing, spray, spin-on, and/or extrusion techniques. The wafers are then loaded into a POCl₃ furnace 206, preferably with front-to-front, back-to-back configuration.

The cell wafers are then heated up to the desired diffusion temperature, preferably between 800-1000° C., and co-diffusion takes place in order to form the p⁺ region from the p-type dopant and n⁺ region from POCl₃ source 208. POCl₃ may be used as liquid dopant through which a carrier gas including oxygen is bubbled. However, at higher temperatures, POCl₃ may fill the diffusion chamber as a gas during the emitter diffusion process. Diffusion occurs from the region of high electron concentration (n-type side) to the region of low electron concentration (p-type side). After the co-diffusion process, the wafers are wet processed to remove surface residue, phosphosilicate glass, and/or borosilicate glass 210. Finally, a formation of n⁺-p-p⁺/p⁺-n-n⁺ structure is completed by edge isolation 212, using any conventional method known in the art, such as laser scribing, plasma barrel etching, dry etching, inline wet etching.

It is an aspect of this invention that the p-type and n-type dopants have dissimilar diffusion constants. These differences may be accommodated by selectively subjecting the slower diffusing dopant to a more extended (more time, more temperature, or both) diffusion profile. For example, a boron-deposited wafer (slower diffusion) may be heated up first, followed by turning on the POCl₃ source for phosphor diffusion. A problem encountered with the simultaneous diffusion of the p- and n-type dopants is that typically one will diffuse faster and hence to a greater depth than the other. By way of example only, boron diffuses more slowly than phosphorous into silicon and liquid or gas phase dopant sources diffuse more quickly than solid phase dopant sources. This makes it difficult to optimize the diffusion profile of both dopants if they are subjected to exactly the same thermal profile (time and temperature). To overcome this problem, a dopant may be introduced with a reduced thermal profile relative to a solid source dopant that has been applied to the wafer, thereby reducing the dopant diffusion. For example, if the solid dopant source contains boron, and the liquid or gas dopant source is a POCl₃ source, the first portion of the thermal profile in the diffusion furnace is applied without the introduction of POCl₃. The furnace ambient may be, for example, vacuum or an inert gas. After the boron is diffused to a desired depth, the phosphorous may be introduced and diffused to its required depth. This may optionally be done at a lower temperature to further slow diffusion. Allowing the p-type dopant source to maintain a different thermal profile than the n-type dopant source enables a highly desirable structure for n-type emitter cells, namely a shallow phosphorous emitter. This structure maximizes the cell efficiency by minimizing the so called “dead layer” on the cell surface which occurs due to thick emitter layers that absorb light but do not create photocurrent, thereby degrading cell performance.

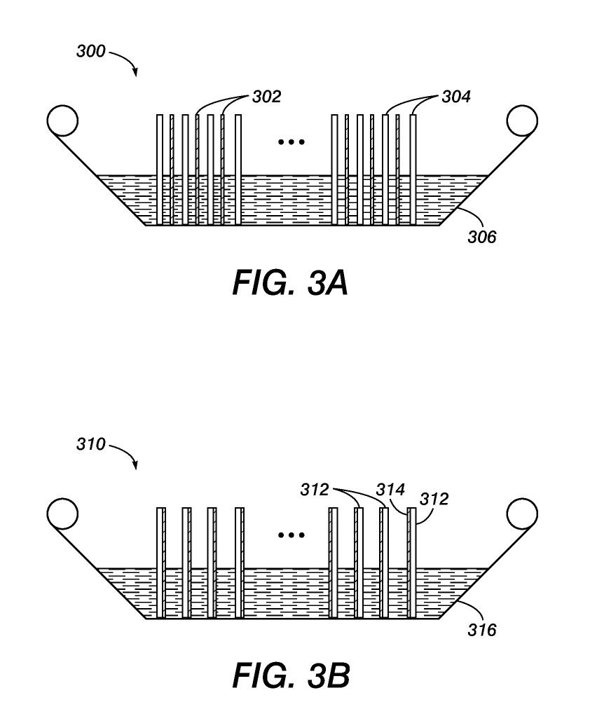

FIGS. 3A and 3B illustrate one embodiment of the preferred cell wafer loading configuration (FIG. 3B) into a tube furnace, compared to a conventional loading configuration (FIG. 3A). The present loading configuration of cell wafers during the diffusion process provides a higher throughput, i.e. the rate at which solar cell substrates are processed, compared to the conventional configuration. Two wafers 312, 314 can be placed into one slot 316 for the diffusion process, instead of one wafer 304 into one slot 306 for a conventional loading. Using two wafers increases a cell's productivity and the overall efficiency of the cell. Additionally, the present cell wafer loading configuration (FIG. 3B) eliminates the need to place dopant source wafers 302 between the cell wafers in order to create the emitter and back surface field of a solar cell. Therefore, only cell wafers are loaded into the furnace leading to a high throughput compared to the conventional configuration.

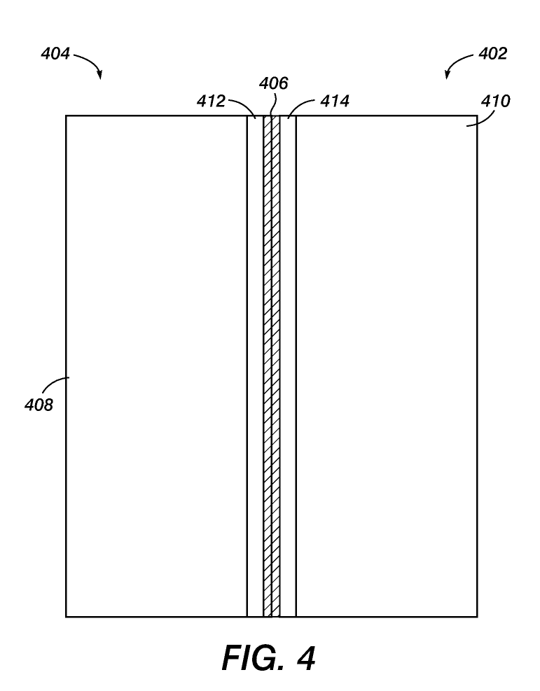

A diffusion barrier layer 406 may be deposited on top of dopant source layers 412, 414 to isolate the n⁺ region from the p⁺ region during contact formation, as shown in FIG. 4. FIG. 4 displays the use of two semiconductor substrates 408, 410, in which dopant source layers 412, 414 are deposited over the substrate layers 408, 410 of cell wafers 402, 404. The configuration is such that the first and second dopant source layers 412, 414 face each other. A diffusion barrier 406 may then be deposited over the dopant source layers 412, 414. Typical materials commonly used for diffusion barriers include silicon dioxide (SiO₂), silicon nitride (SiNₓ) and silicon carbide (SiC) layers, and other similar material known in the art. The addition of a diffusion barrier 406 also helps block impurities from diffusing into silicon during the high temperature treatments. The diffusion barrier 406 can be deposited simultaneously with the dopant 412, 414 or separately, using techniques known in the art, such as is described in US20070110836(A1), “Extrusion/Dispensing Systems and Methods.”

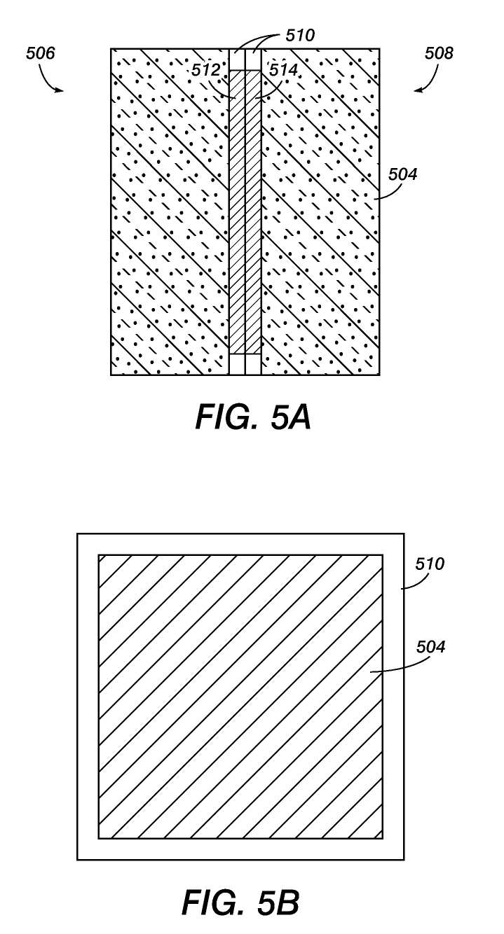

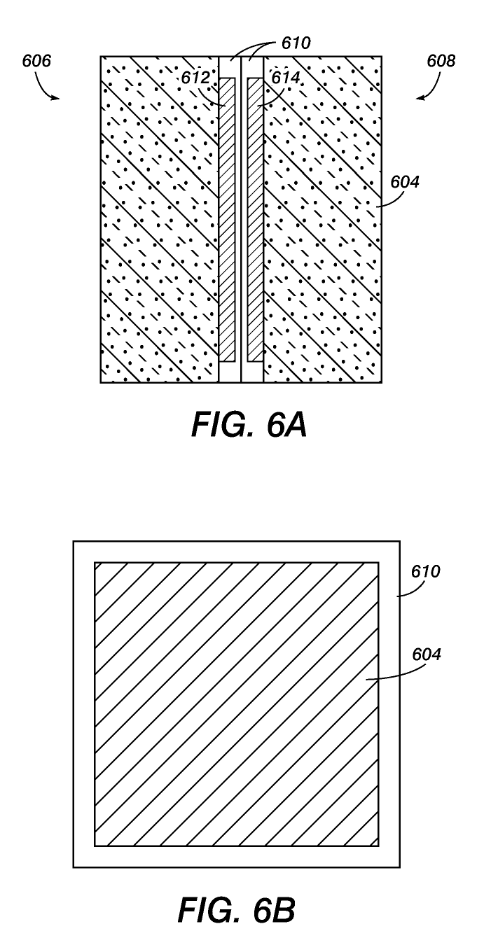

FIGS. 5(A, B) and 6(A, B) exemplify a variation of the structure depicted in FIG. 4. FIGS. 5A and B illustrate the deposition of dopant 512, 514 and diffusion barrier 510 on the same side of substrate 504 of cell wafers 506, 508. The cross-sectional view (FIG. 5A) displays how the dopant source 512, 514 is deposited with the diffusion barrier layer 510, but does not completely cover each dopant source 512, 514. Similarly, FIG. 6A illustrates the deposition of the dopant source 612, 614 and diffusion barrier layer 610 on the same side of the silicon substrate 604 of cell wafers 606, 608. Diffusion barrier layer 610 may cover only a portion of substrate 604. The dopant source 612, 614 is completely covered with the diffusion barrier layer 610. It should be noted that both the structures depicted in FIGS. 5 and 6 eliminate the need for the edge isolation process by the addition of the diffusion barrier regions 510, 610 around the wafer edges. This is because the n⁺ and p⁺ diffused regions are separated and avoid a cross doping effect during the drive-in process in a furnace. A portion of barrier layer 510, 610 is in direct contact with a portion of the back surface of the substrate 504, 604. Moreover, the diffusion barrier acts as a cap to prevent the dopants in the solid state from escaping into the gas phase and re-depositing elsewhere on the cells, which could result in an altered doping profile.

This invention need not be used solely for the fabrication of bifacial cells. It may, for example, be desirable to place metallization over the entire back surface of the cell so that it serves as a back surface reflector. Because this method provides a diffused back surface field over the majority of the wafer surface, it is not necessary for example to metalize with aluminum and diffuse it in as is commonly done to form the base of a standard screen printed H cell. Therefore, it is possible to introduce a back surface passivation using a dielectric. With a dielectric in place, it is also possible to include a back surface reflector with greater reflectivity than the conventional screen printed aluminum paste that is commonly used. Electrical contacts to the silicon can be made, for example, through a set of openings (slots or holes) in the back surface passivation. Such openings can, for example, be produced by laser ablation or by chemical etching. The cell efficiency can thereby be improved in two ways: (1) by better passivating the cell back surface (0.4-0.5% increase in absorption efficiency by improving back surface recombination velocity from 600 to 150 cm/s) and by (2) by improving the reflectivity of the back surface (0.3-0.5% increase in absorption efficiency by improving back surface reflection from 60 to 90%).

Practically, it may be difficult to determine if one furnace step or two is employed. However, it is possible that there will be structural signatures on the wafer resulting from this process because it may use any of liquid, gas and solid phase dopant sources. For example, the lateral profile of dopants at the edges of liquid source diffusion may be differentiable from that produced by other methods because of the abruptness and feature definition at the edges. The diffusion depths will correspond to different time-temperature profiles for the diffusing dopants.

It will be appreciated that various of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A method for diffusing two dissimilar dopant materials onto a semiconductor: substrate in a single thermal processing step, said method comprising:
placing a first dopant source on a semiconductor substrate;
placing the substrate into a thermal processing chamber comprising one or more slots;
subjecting said substrate to a thermal profile; and
heat treating said substrate in the presence of a second dopant source.

2. The method of claim 1 wherein a portion of the thermal profile is carried out with the presence said second dopant source substantially reduced or eliminated.

3. The method of claim 1 further comprising covering a portion of the substrate with a diffusion barrier material.

4. The method of claim 3 wherein the diffusion barrier material is in direct contact with a portion of a back surface of the substrate.

5. The method of claim 3 wherein the diffusion barrier covers at least a portion of the first and second dopant source.

6. The method of claim 1, further comprising two or more semiconductor substrates.

7. The method of claim 1, wherein said first dopant is a solid-phase dopant and said second dopant is a liquid-phase dopant.

8. The method of claim 8, wherein two semiconductor substrates are loaded into one thermal processing chamber slot such that the first and second dopant source face each other.

9. A method for doping a semiconductor substrate, said method comprising;
placing a first dopant source on a first surface of a first cell wafer;
placing a second dopant source on a second surface of a second cell wafer;
arranging said first and second cell wafer in a tube furnace such that said first and second surfaces face one another; and
co-diffusing said first and second cell wafer in the presence of a third dopant source.

10. The method according to claim 9, further comprising placing a diffusion barrier layer between said first and second wafers.

11. The method of claim 9, wherein said first dopant source is a solid-phase dopant and said third dopant source is a liquid-phase dopant.

12. The method of claim 9, further comprising diffusing said first and second dopant source in one thermal processing step.

13. The method of claim 10, wherein said diffusion barrier layer completely covers said first and second dopant source.

14. The method of claim 10, wherein said diffusion barrier layer is situated in direct contact with said semiconductor wafer.

15. The method of claim 10, wherein the diffusion barrier layer is situated at an edge of said first and said second wafer.

16. A semiconductor arrangement for dopant diffusion into a substrate, comprising:
at least a first and second cell wafer, wherein each wafer comprises a first and second side;
a p-type dopant source deposited on the first side of said first and second cell wafer; and
an n-type dopant source deposited on the second side of said first and second cell wafer, wherein said first and second cell wafer are loaded into a furnace with back-to-back/front-to-front configuration.

17. The semiconductor arrangement of claim 16, wherein said p-type dopant source and said n-type dopant source maintain different thermal profiles.

18. The semiconductor arrangement of claim 16, further comprising a diffusion barrier between said first and second cell wafer.

19. The semiconductor arrangement of claim 18, wherein said diffusion barrier covers each of said p- and n-type dopant source.

20. The semiconductor arrangement of claim 16, wherein one of said p- and n-type dopant source is a solid and one of said p- and n-type dopant source is a liquid.
